(19) United States
(12) Patent Application Publication
(10) Pub. No.: US 2024/0284654 A1
(43) Pub. Date: Aug. 22, 2024

(54) SRAM HAVING CFET STACKS AND METHOD OF MANUFACTURING SAME

(71) Applicant: TAIWAN SEMICONDUCTOR MANUFACTURING COMPANY, LTD., Hsinchu (TW)

(72) Inventors: Yen-Lin CHUNG, Hsinchu (TW); Kao-Cheng LIN, Hsinchu (TW); Wei Min CHAN, Hsinchu (TW); Yen-Huei CHEN, Hsinchu (TW)

(21) Appl. No.: 18/519,633

(22) Filed: Nov. 27, 2023

Related U.S. Application Data
(60) Provisional application No. 63/485,326, filed on Feb. 16, 2023.

(51) Int. Cl. H10B 10/00

(52) U.S. Cl. CPC H10B 10/125

(57) ABSTRACT

A static random access memory (SRAM) includes: first and second CFET stacks, each of which includes a first active region (AR), e.g., N-type, stacked in a first direction on a second AR (e.g., P-type), each CFET stack representing a complementary FET (CFET) architecture; an upper half of a third CFET stack; a lower half of a fourth CFET stack; the first and second CFET stacks including FETs that comprise a latch of the SRAM; the first CFET stack further including FETs that comprise first and third ports of the SRAM; the second CFET stack further including FETs that comprise second and fourth ports of the SRAM; the lower half of the fourth CFET stack including FETs that comprise a fifth port of the SRAM; and the upper half of the third CFET stack including FETs that comprise a sixth port of the SRAM.

### PRIORITY

The present application claims the priority of U.S. Provisional Application No. 63/485,326, filed Feb. 16, 2023, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a schematic circuit diagram, in accordance with some embodiments.

FIGS. 2A-2B are corresponding layout diagrams of SRAMs for semiconductor devices, in accordance with some embodiments.

FIGS. 3A-3C are corresponding cross-sectional views of SRAMs for semiconductor devices, in accordance with some embodiments.

FIGS. 3D-3E are corresponding side views of SRAMs for semiconductor devices, in accordance with some embodiments.

FIG. 4 is a schematic circuit diagram, in accordance with some embodiments.

FIGS. 5A-5B are corresponding layout diagrams of SRAMs for semiconductor devices, in accordance with some embodiments.

FIGS. 6A-6B are corresponding side views of SRAMs for semiconductor devices, in accordance with some embodiments.

FIGS. 7A-7B are flowcharts of corresponding methods of manufacturing a memory device, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower.” “above.” “upper” and the like, are used herein for case of description to describe one element or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

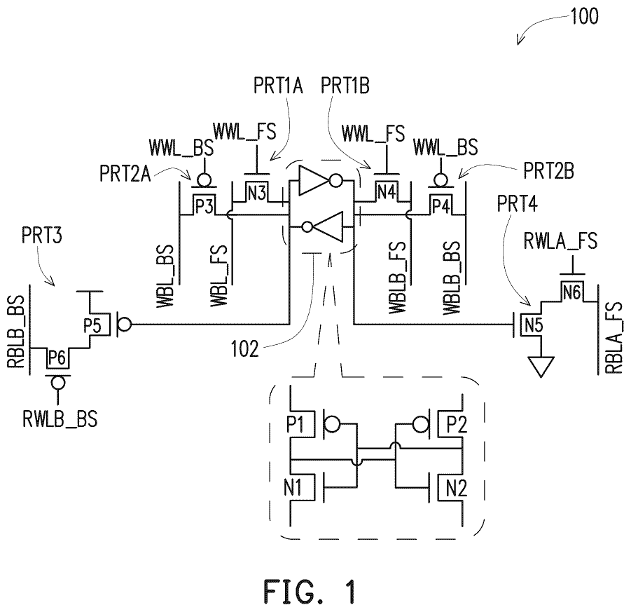

In some embodiments, a static random access memory (SRAM) (e.g., FIG. 1) has a Z-shape. Such an SRAM includes: first (e.g., 208(2)) and second (e.g., 208(3)) CFET stacks, each of which includes a first active region (AR) having a first dopant-type (e.g., N-type) stacked in a first direction (e.g., Z-axis) on a second AR having a second dopant type (e.g., P-type) different than the first dopant type. Each CFET stack represents a complementary field-effect transistor (e.g., CFET) architecture. The SRAM as such further includes an upper half (e.g., N-type AR) of a third CFET stack (e.g., 208(1)) and a lower half (e.g., P-type AR) of a fourth CFET stack (e.g., 208(4)). The first (e.g., 208(2)) and second (e.g., 208(3)) CFET stacks include field-effect transistors (e.g., FETs) (e.g., N1 on P1, N2 on P2) that comprise a latch (e.g., 102) of the SRAM. The first CFET stack (e.g., 208(2)) further includes FETs (e.g., N3, P3) that comprise first (e.g., PRT1A) and third (e.g., PRT2A) ports of the SRAM. The second CFET stack (e.g., 208(3)) further includes FETs (e.g., N4, P4) that comprise second (e.g., PRT1B) and fourth (e.g., PRT2B) ports of the SRAM. The lower half (e.g., P-type AR) of the fourth CFET stack (e.g., 208(4)) includes FETs (e.g., P5-P6) that comprise a fifth port (e.g., PRT3) of the SRAM. The upper half (e.g., N-type AR) of the third CFET stack (e.g., 208(3)) includes FETs (e.g., N5-N6) that comprise a sixth port (e.g., PRT4) of the SRAM. The asymmetry of the Z-shape facilitates abutting instances of the Z-shape such that corresponding portions of the abutting instances overlap/underlap (or nest) with each other. Such overlapping/underlapping (or nesting) conserves space/volume. Some embodiments are directed to a method of manufacturing such Z-shaped SRAMs.

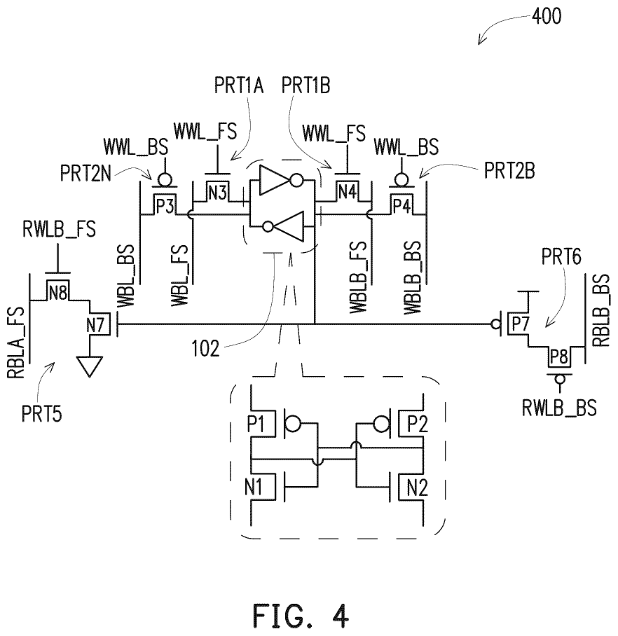

In some embodiments, a static random access memory (SRAM) (e.g., FIG. 4) has a rectangular parallelepiped (RP) shape (RP-shape). Such an SRAM includes: first (e.g., 508(2)), second (e.g., 508(3)) and third (e.g., 508(1)) CFET stacks, each of which includes a first active region (AR) having a first dopant-type (e.g., N-type) stacked in a first direction (e.g., Z-axis) on a second AR having a second dopant type (e.g., P-type) different than the first dopant type, each CFET stack representing a complementary field-effect transistor (CFET) architecture. The first (e.g., 508(2)) and second (e.g., 508(3)) CFET stacks include FETs (e.g., N1 on P1, N2 on P2) that comprise a latch (e.g., 102) of the SRAM. The first CFET stack (e.g., 508(2)) further includes FETs (e.g., N3, P3) that comprise first (e.g., PRT1A) and third (e.g., PRT2A) ports of the SRAM. The second CFET stack (e.g., 508(3)) further includes FETs (e.g., N4, P4) that comprise second (e.g., PRT1B) and fourth (e.g., PRT2B) ports of the SRAM. The third CFET stack (e.g., 508(1)) further includes FETs (e.g., N7-N8, P7-P8) that comprise fifth (e.g., PRT5) and sixth (e.g., PRT6) ports of the SRAM. The symmetry of the RP-shape facilitates abutting instances of the RP-shape. Such abutting conserves space/volume. Some embodiments are directed to a method of manufacturing such RP-shaped SRAMs.

FIG. 1 is a schematic circuit diagram of an SRAM 100, in accordance with some embodiments.

Static random-access memory (SRAM) 100 includes a latch 102 and ports PRT1, PRT2, PRT3 and PRT4. Port PRT1 includes sub-ports PRT1A and PRT1B. Port PRT2 includes sub-ports PRT2A and PRT2B. As such, SRAM 100 is a four port (4P) SRAM. As discussed below, SRAM 100 includes twelve transistors (T), i.e., is a 12T SRAM. In some embodiments, SRAM 100 is referred to as a 12T4P SRAM, where 12T4P indicates twelve transistors and four ports.

SRAM 100 has a complementary metal-oxide semiconductor (CMOS) architecture which includes field-effect transistors (FETs). More particularly, SRAM 100 includes positively-doped (or positive channel) metal-oxide semiconductor (PMOS) FETs (PFETs) and negatively-doped (or negative channel) metal-oxide semiconductor (NMOS) FETs (NFETs).

SRAM 100 includes a latch 102. Latch 102 includes: PFETs P1 and P2 and NFETs N1 and N2. P1 and N1 are coupled in series between a first reference voltage and a second reference voltage. P2 and N2 are coupled in series between the first reference voltage and the second reference voltage. In some embodiments, the first reference voltage is VDD and the second reference voltage is VSS. In some embodiments, the first and second reference voltages are voltages correspondingly other than VDD and VSS. First and second source/drain (S/D) terminals of P1 are correspondingly coupled to VDD and a first S/D terminal of N1. A second S/D terminal of N1 is coupled to VSS. First and second S/D terminals of P2 are correspondingly coupled to VDD and a first S/D terminal of N2. A second S/D terminal of N2 is coupled to VSS. Gate terminals of P1 and N1 and corresponding S/D terminals of P2 and N2 are coupled together. Gate terminals of P2 and N2 and corresponding S/D terminals of P1 and N1 are coupled together. The coupling between the second S/D terminal of P1 and the first S/D terminal of N1 represents a first input/output (I/O) node of latch 102. The coupling between the second S/D terminal of P2 and the first S/D terminal of N2 represents a second I/O node of latch 102.

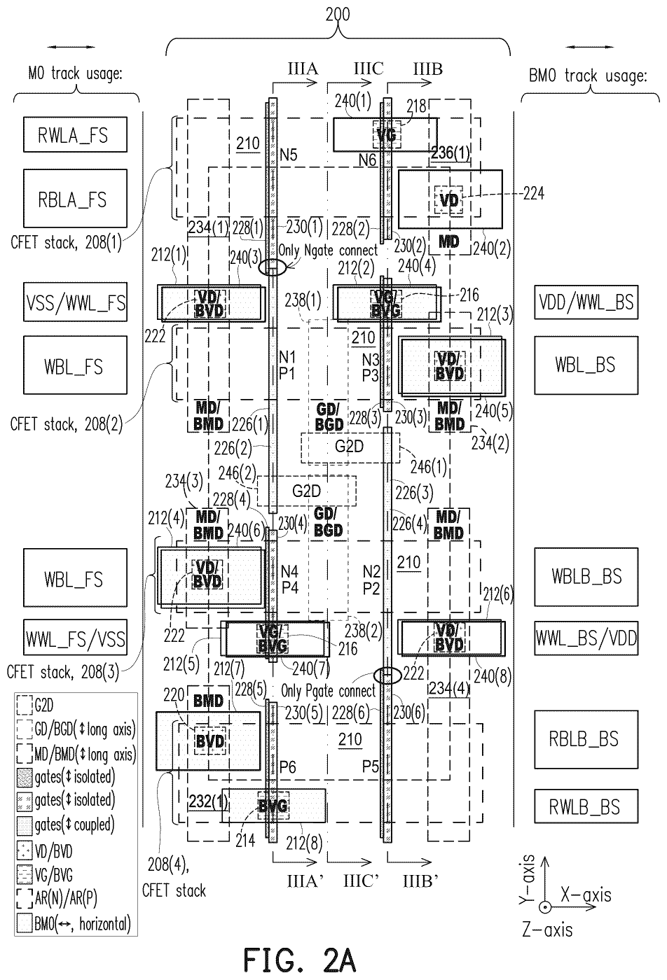

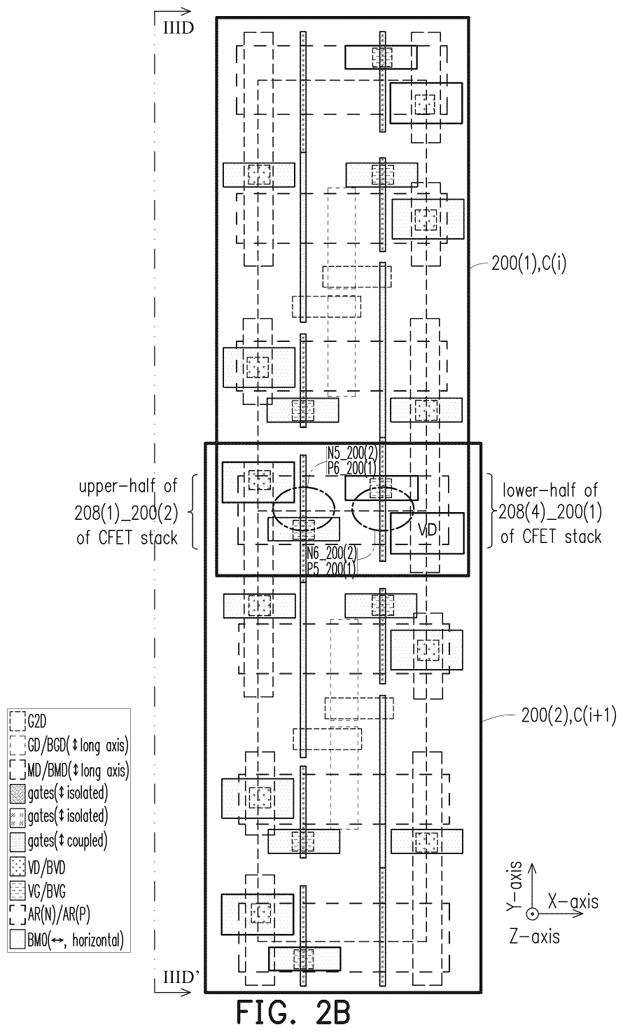

In FIG. 1, recalling that port PRT1 includes sub-ports PRT1A and PRT1B, sub-port PRT1A includes an NFET N3 coupled between a bit line WBL_FS and corresponding S/D terminals of P1 and N1 of latch 102, where the suffix FS indicates that bit line WBL_FS is on a front/upper side (FS) of a corresponding semiconductor device (FIG. 2A). Sub-port PRT1B of port PRT1 includes an NFET N4 coupled between a bit_bar line WBLB_FS and corresponding S/D terminals of P2 and N2 of latch 102. Gate terminals of N3 and N4 of PRT1 are coupled to a word line WWL_FS.

Recalling that port PRT2 includes sub-ports PRT2A and PRT2B, sub-port PRT2A includes a PFET P3 coupled between a bit line WBL_BS and corresponding S/D terminals of P1 and N1 of latch 102, where the suffix BS indicates that bit line WBL_BS is on a back/lower side (BS) of a corresponding semiconductor device (FIG. 2A). Sub-port PRT2B of port PRT2 includes a PFET P4 coupled between a bit line WBLB_BS and corresponding S/D terminals of P2 and N2 of latch 102. Gate terminals of P3 and P4 of PRT2 are coupled to a word line WWL_BS.

In FIG. 1, port PRT3 includes PFETs P5 and P6. The S/D terminals of P5 are correspondingly coupled between VDD and a first S/D terminal of P6. The second S/D terminal of P6 is coupled to a bit line RBLB_BS. A gate terminal of P5 is coupled to corresponding S/D terminals of P1 and N1 at the first I/O node of latch 102. A gate terminal of P6 is coupled to a word line RWLB_BS.

Port PRT4 includes NFETs N5 and N6. The S/D terminals of N5 are correspondingly coupled to VSS and a first S/D terminal of N6. The second S/D terminal of N6 is coupled to a bit line RBLA_FS. A gate terminal of N5 is coupled to corresponding S/D terminals of P2 and N2 at the second I/O node of latch 102. A gate terminal of N6 is coupled to a word line RWLA_FS.

FIG. 2A is a layout diagram of an SRAM 200 for a semiconductor device, in accordance with some embodiments.

The layout diagram of FIG. 2A is representative of a semiconductor device. Structures in the semiconductor device are represented by patterns (also known as shapes) in the layout diagram. For simplicity of discussion, elements in the layout diagram of FIG. 2A (and of other figures included herein) will be referred to as if they are structures rather than patterns per se. For example, pattern 228(1) represents an M0 segment. In the following discussion, element 228(1) is referred to as M0 segment 228(1) rather than as M0 pattern 228(1).

In FIG. 2A, as well as in other layout diagrams of the present document, an orthogonal Cartesian coordinate system is assumed in which a first direction is parallel to the X-axis, a second direction is parallel to the Y-axis and a third direction is parallel to the Z-axis. A layout diagram per se is a top view. Shapes in the layout diagram are two-dimensional relative to, e.g., the X-axis and the Y-axis, whereas the semiconductor device being represented is three-dimensional. Typically, relative to the Z-axis, the semiconductor device is organized as a stack of layers in which are located corresponding structures, i.e., to which belong corresponding structures. Accordingly, each shape in the layout diagram represents, more particularly, a component in a corresponding layer of the corresponding semiconductor device. Also, typically, the layout diagram represents relative depth, i.e., positions along the Z-axis, of shapes and thus layers by superimposing a second shape on a first shape so that the second shape at least partially overlaps the first shape. Regarding some structures which are stacked in a layout diagram along the Z-axis, the stacking order along the Z-axis is distorted in some respects relative to the corresponding semiconductor device, this being done in the layout diagram, e.g., FIG. 2A, for simplicity of illustration. For example, MD/BD contact 234(3) is shown as a single structure in FIG. 2A whereas MD/BMD contact 234(3) represents two structures, namely a BMD contact that is around a corresponding portion of the P-type AR of CFET stacks 208(3) and an overlaying MD contact that is around a corresponding portion of the N-type AR of CFET stack 208(3).

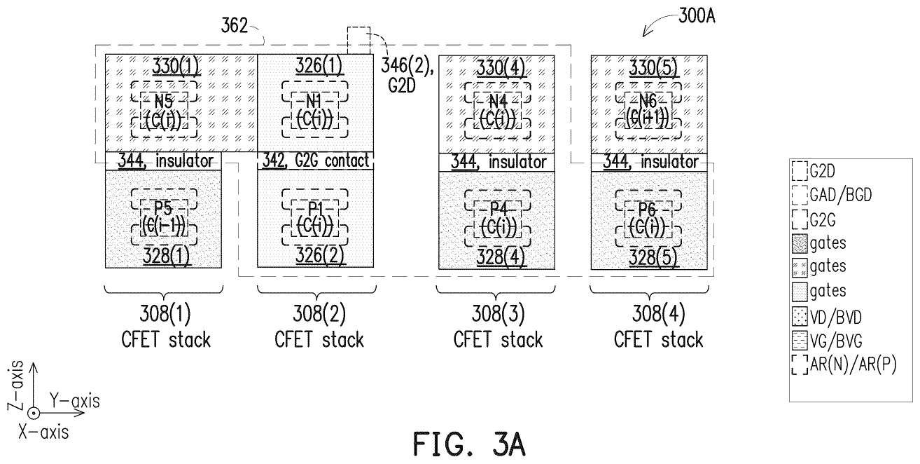

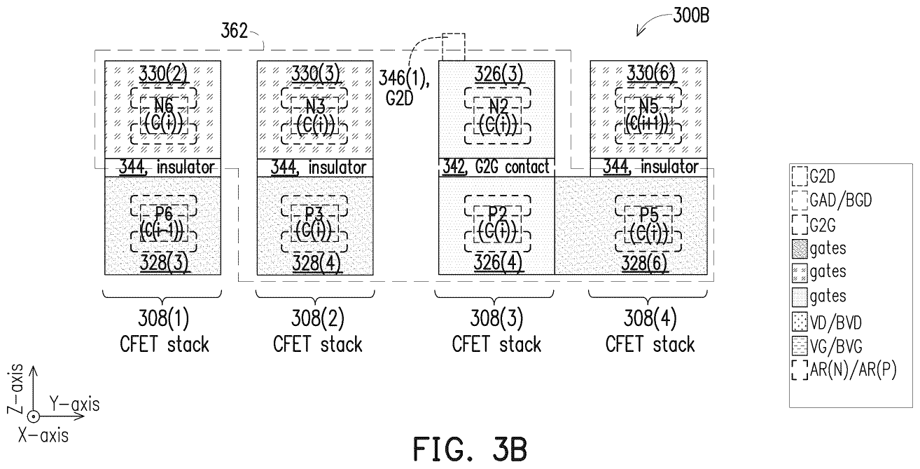

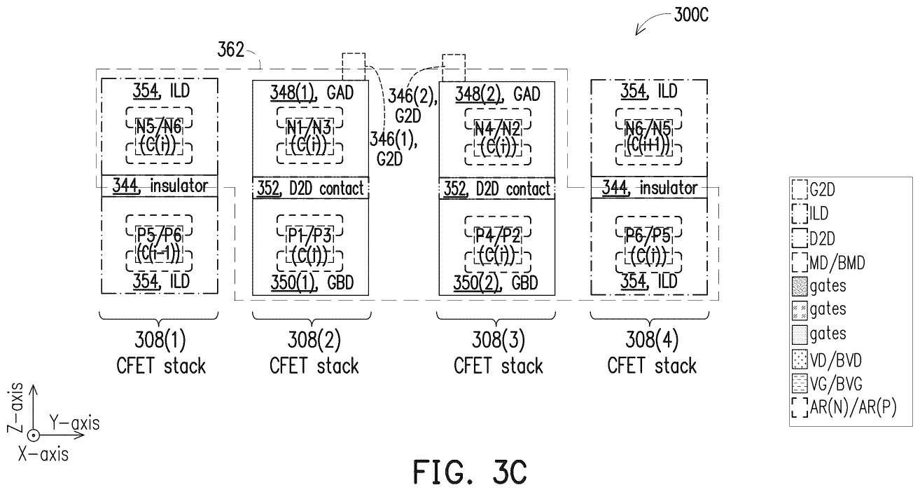

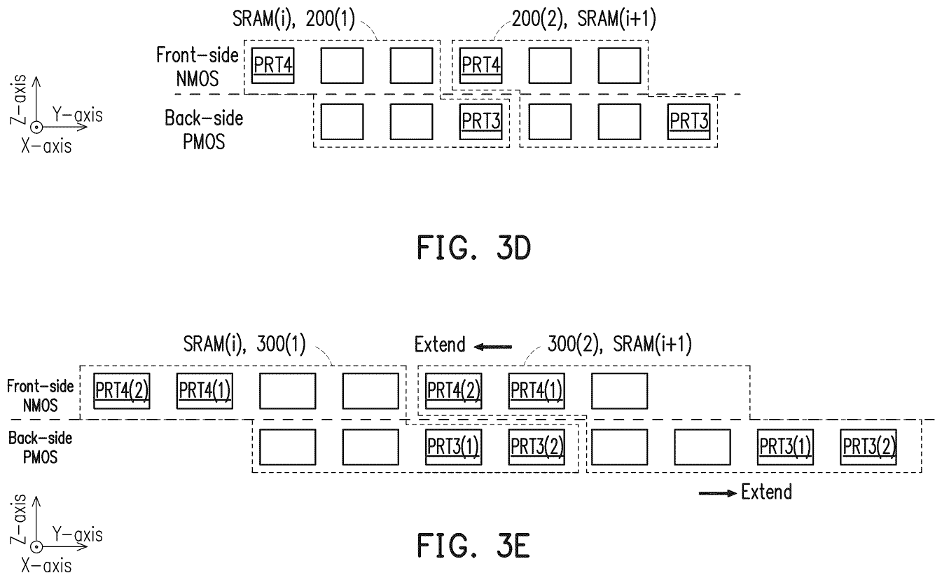

In FIG. 2A, section line IIIA-IIIA′ extending parallel to the Y-axis in FIG. 3A corresponds to cross-section of FIG. 3A. Section line IIIB-IIIB′ extending parallel to the Y-axis in FIG. 3A corresponds to cross-section of FIG. 3B. Section line IIIC-IIIC′ extending parallel to the Y-axis in FIG. 3A corresponds to cross-section of FIG. 3C.

SRAM 200 is an example of SRAM 100 of FIG. 1. As such, SRAM 200 is a 12T4P SRAM that includes NFETs N1-N6 and PFETs P1-P6. SRAM 200 has a complementary field effect transistor (CFET) architecture that includes CFET stacks 208(2)-208(3), an upper half of stack CFET 208(1) and a lower half of CFET stack 208(4). CFET stacks 208(1)-208(4) are separated from each other relative to the Y-axis.

Relative to the Z-axis, each of CFET stacks 208(1)-208(4) includes a stack of first and second active regions (ARs) in which the first active region is stacked over the second active region. Each of CFET stacks 208(1)-208(4) includes two pairs of FETs, each pair including an NFET and a PFET stacked on each other relative to the Z-axis. Components of the NFETs and PFETs are discussed below.

CFET stack 208(1) includes: a first pair of N5 stacked over P5 (not shown in FIG. 2A but see FIG. 3B), and a second pair of N6 stacked over P6 (not shown in FIG. 2A but see FIG. 3B). Though included in CFET stack 208(1), P5 and P6 are not amongst the FETs which comprise SRAM 200, and so P5 and P6 are not labeled in FIG. 2A.

CFET stack 208(2) includes: a third pair of N1 stacked over P1, and a fourth pair of N3 stacked over P3. CFET stack 208(3) includes: a fifth pair of N4 stacked over P4, and a fifth pair of N2 stacked over P2.

CFET stack 208(4) includes: a seventh pair of N6 (not shown in FIG. 2A but FIG. 3A) stacked over P6, and an eighth pair of N5 (not shown in FIG. 2A but FIG. 3A) stacked over P5. Though included in CFET stack 208(4), N5 and N6 are not amongst the FETs which comprise SRAM 200, and so P5 and P6 are not labeled in FIG. 2A.

In SRAM 200, each first AR has a first dopant-type (e.g., N-type) and each second AR has a second dopant type (e.g., P-type) different than the first dopant type such that the first AR is an N-type AR and the second AR is a P-type AR. In some embodiments, the first dopant is a P-type dopant and the second dopant is an N-type dopant such that the first AR is a P-type AR and the second AR is an N-type AR. Long axes of the N-type and P-type ARS extend parallel to the X-axis. N-type ARs are stacked on corresponding P-type ARs relative to the Z-axis. Each instance of an N-type AR stacked on a corresponding instance of P-type AR is assigned reference number 210 in FIG. 2A.

Gates are formed around a corresponding portion of an N-type AR or a P-type AR. Three types of gate are included in SRAM 200. Examples of the first type gate are gates 226(1)-226(4), or the like. Relative to the Y-axis, the first type of gate is one in which a first instance of the first-type gate is coupled with a second instance of the first-type gate, e.g., by an instance of a gate-to-gate (G2G) contact (e.g., G2G contact 342 of FIGS. 3A-3B), where the first instance is formed around a corresponding portion of an N-type AR and the second instance is formed around a corresponding portion of a P-type AR, or vice-versa, and where the first and second instances are aligned relative to the X-axis.

Gates 226(1) and 226(2) are formed around corresponding portions of the N-type and P-type ARs of CFET stack 208(2). As such, gate 226(1) is over gate 226(2) relative to the Z-axis, and gate 226(1) is aligned with gate 226(2) relative to the X-axis. Gates 226(1) and 226(2) correspondingly represent the gate terminals of N1 and P1. Gate 226(1) is also coupled to gate 230(1). Gate 226(3) and 226(4) are formed around corresponding portions of the N-type and P-type ARs of CFET stack 208(3). As such, gate 226(3) is over gate 226(4) relative to the Z-axis, and gate 226(3) is aligned with gate 226(4) relative to the X-axis. Gates 226(3) and 226(4) correspondingly represent the gate terminals of N2 and P2. Gate 226(4) is also coupled to gate 228(6).

In SRAM 200, examples of the second type of gate are gates 228(1)-228(4), or the like. Relative to the Z-axis, the second type of gate is free from being coupled vertically to the corresponding overlying gate, e.g., because of an instance of an insulator (e.g., insulator 344 FIGS. 3A-3B) formed therebetween, where the second type of gate is a gate formed around a portion of a P-type AR.

Gate 228(1) is formed around a first portion of the P-type AR of CFET stack 208(1) and is free from being coupled to corresponding overlying gate 230(1). Gate 228(2) is formed around a second portion of the P-type AR of CFET stack 208(1) and is free from being coupled to corresponding overlying gate 230(2). Gate 228(3) is formed around a portion of the P-type AR of CFET stack 208(2) and is free from being coupled to corresponding overlying gate 230(3). Gate 228(4) is formed around a portion of the P-type AR of CFET stack 208(3) and is free from being coupled to corresponding overlying gate 230(4). Gate 228(5) is formed around a first portion of the P-type AR of CFET stack 208(4) and is free from being coupled to corresponding overlying gate 230(5). Gate 228(6) is formed around a second portion of the P-type AR of CFET stack 208(4) and is free from being coupled to corresponding overlying gate 230(6). Gates 228(1)-228(6) are aligned correspondingly with gates 230(1)-230(6) relative to the X-axis.

In SRAM 200, examples of the third type of gate are gates 230(1)-230(4), or the like. Relative to the Z-axis, the third type of gate is free from being coupled vertically to the corresponding underlying gate, e.g., because of an instance of an insulator 332 (FIGS. 3A-3B) formed therebetween, where the third type of gate is a gate formed around a portion of an N-type AR.

Gate 230(1) is formed around a first portion of the N-type AR of CFET stack 208(1) and is free from being coupled to corresponding underlying gate 228(1). Gate 230(2) is formed around a second portion of the N-type AR of CFET stack 208(1) and is free from being coupled to corresponding underlying gate 228(2). Gate 230(3) is formed around a portion of the N-type AR of CFET stack 208(2) and is free from being coupled to corresponding underlying gate 228(3). Gate 230(4) is formed around a portion of the N-type AR of CFET stack 208(3) and is free from being coupled to corresponding underlying gate 228(4). Gate 230(5) is formed around a first portion of the N-type AR of CFET stack 208(4) and is free from being coupled to corresponding underlying gate 228(5). Gate 230(6) is formed around a second portion of the N-type AR of CFET stack 208(4) and is free from being coupled to corresponding underlying gate 228(6).

In FIG. 2A, SRAM 200 includes a metal-to-S/D (MD) contact 236(1), a buried MD (BMD) contact 232(1) and MD/BMD contacts 234(1)-234(4), long axes of which extend parallel to the Y-axis.

MD contact 236(1) is formed around a source/drain (S/D) region in the P-type AR of CFET stack 208(1). Regarding S/D regions, formation of each N-type AR includes doping first areas of the N-type AR to form corresponding S/D regions. The S/D regions of the N-type ARs are examples of first transistor-components. Second areas of the N-type ARs between corresponding S/D regions of the N-type are channel regions and are examples of second transistor-components. In some embodiments, each MD contact is formed against one or more surfaces of the corresponding S/D region but not around the S/D region.

BMD contact 232(1) is formed around an S/D region in the P-type AR of CFET stack 208(1). Also regarding the S/D regions, formation of each P-type AR includes doping first areas of the P-type AR to form corresponding S/D regions. The S/D regions of the P-type ARs also are examples of the first transistor-components. Second areas of the P-type ARs between corresponding S/D regions of the P-type ARs are channel regions and also are examples of the second transistor-components. In some embodiments, each BMD contact is formed against one or more surfaces of the corresponding S/D region but not around the S/D region.

In FIG. 2A, each of MD/BMD contacts 234(1)-234(4) represents two structures, namely an instance of an MD contact that is around a portion of the N-type AR in a given CFET stack and an instance of a BMD contact that is around a corresponding portion of the P-type AR in the given CFET stack. MD/BMD contact 234(1) represents an instance of an MD contact formed around portions of the N-type ARs in CFET stacks 208(1) and 208(2) and an instance of a BMD contact formed around corresponding portions of the P-type ARs in CFET stacks 208(1) and 208(2). MD/BMD contact 234(2) represents an instance of an MD contact formed around a portion of the N-type AR in CFET stack 208(2) and an instance of a BMD contact formed around a corresponding portion of the P-type AR in CFET stack 208(2). MD/BMD contact 234(3) represents an instance of an MD contact formed around a portion of the N-type AR in CFET stack 208(3) and an instance of a BMD contact formed around a corresponding portion of the P-type AR in CFET stack 208(3). MD/BMD contact 234(4) represents an instance of an MD contact formed around portions of the N-type ARs in CFET stacks 208(3) and 208(4) and an instance of a BMD contact formed around corresponding portions of the P-type ARs in CFET stacks 208(3) and 208(4).

SRAM 200 of FIG. 2A further includes M_1st segments (which are conductors) in a first layer of metallization (MET_1st layer) over CFET stacks 208(1)-208(4), i.e., are on a front side of CFET stacks 208(1)-208(4). In FIG. 2A, and likewise for other figures in the present document, a numbering convention is assumed in which the M_1st layer of metallization is referred to as MET0, and correspondingly a first layer of interconnection (VIA_1st layer) (not shown) over the MET0 layer is referred to as VIA_0. In some embodiments, depending upon the numbering convention of the corresponding process node by which a semiconductor device is manufactured, the MET_1st layer is Ml and correspondingly the VIA_1st layer is VIA1. The M0 segments include M0 segments 240(1)-240(8), long axes of which extend parallel to the X-axis.

Relative to the Y-axis, each of M0 segments 240(1)-240(8) has a midline (not shown), where the midline itself extends parallel the X-axis. The midlines of M0 segments 240(1)-240(8) are substantially collinear with corresponding horizontal reference tracks (not shown). In FIG. 2A, a signal on a given M0 segment is indicated in a column to the left of SRAM 200, the column being labeled ‘M0 track usage.’

M0 segment 240(1) has the signal on word line RWLA_FS. M0 segment 240(2) has the signal on bit line RBLA_FS. M0 segment 240(3) has VSS. M0 segment 240(4) has the signal on word line WWL_FS. M0 segment 240(5) has the signal on bit line WBL_FS. M0 segment 240(6) has the signal on bit bar line WBLB_FS. M0 segment 240(7) has the signal on word line WWL_FS. M0 segment 240(8) has VSS.

SRAM 200 of FIG. 2A further includes BM_1st segments (which are conductors) in a first layer of metallization (MET_1st layer) under CFET stacks 208(1)-208(4), i.e., are on a back side of CFET stacks 208(1)-208(4). In FIG. 2A, and likewise for other figures in the present document, a numbering convention is assumed in which the BM_1st layer of metallization is referred to as BMET0, and correspondingly a first layer of interconnection (BVIA_1st layer) (not shown) under the BMET0 layer is referred to as BVIA_0. In some embodiments, depending upon the numbering convention of the corresponding process node by which a semiconductor device is manufactured, the BMET_1st layer is BM1 and correspondingly the BVIA_1st layer is BVIA1. The BM0 segments include BM0 segments 212(1)-212(8), long axes of which extend parallel to the X-axis.

Relative to the Y-axis, each of BM0 segments 212(1)-212(8) has a midline (not shown), where the midline itself extends parallel the X-axis. The midlines of BM0 segments 212(1)-212(8) are substantially collinear correspondingly with the horizontal reference tracks (not shown). In FIG. 2A, a signal on a given BM0 segment is indicated in a column to the right of SRAM 200, the column being labeled ‘BM0 track usage.’

BM0 segment 212(1) has VDD. BM0 segment 212(2) has the signal on word line WWL_BS. BM0 segment 212(3) has the signal on word line WBL_BS. BM0 segment 212(4) has the signal on word line WBLB_BS. BM0 segment 212(5) has the signal on word line WWL_BS. BM0 segment 212(6) has VDD. BM0 segment 212(7) has the signal on bit bar line RBLB_BS. BM0 segment 212(8) has the signal on word line RWLB_BS.

In FIG. 2A, SRAM 200 further includes instances of a via-to-gate (VG) contacts 218; instances of a buried VG (BVG) contact 214, and instances of VG/BVG contacts 216. Each instance of VG contact 218 is between a portion of a corresponding one of M0 segments 240(1)-240(8) and a portion of a corresponding one of the gates, e.g., gate 230(2), or the like. Each instance of BVG contact 214 is between a portion of a corresponding one of BM0 segments 212(1)-212(8) and a portion of a corresponding one of the gates, e.g., gate 228(5).

Each instance of VG/BVG contact 216 represents two structures, namely an instance of VG contact 218 and an instance of BVG contact 214 that are aligned with each other relative to each of the X-axis and the Y-axis. For example, parts of an instance of VG/BVG are correspondingly above gate 230(3) and below gate 228(3). Parts of another instance of VG/BVG are correspondingly above gate 230(4) and below gate 228(4).

In FIG. 2A. SRAM 200 further includes instances of a via-to-S/D (VD) contacts 224; instances of a buried VD (BVD) contact 220, and instances of VD/BVD contacts 222. Each instance of VD contact 224 is between a portion of a corresponding one of M0 segments 240(1)-240(8) and a portion of a corresponding the MD contacts, e.g., MD contact 236(1), or the like. Each instance of BVD contact 220 is between a portion of a corresponding one of BM0 segments 212(1)-212(8) and a portion of a corresponding one of the BMD contacts, e.g., BMD contact 232(1), or the like.

Each instance of VD/BVD contact 222 represents two structures, namely an instance of VD contact 224 and an instance of BVD contact 220 that are aligned with each other relative to each of the X-axis and the Y-axis. For example, parts of an instance of VD/BVD contact 222 correspondingly are above and below MD/BMD contact 234(1). Parts of an instance of VD/BVD contact 222 correspondingly are above and below MD/BMD contact 234(2). Parts of an instance of VD/BVD contact 222 correspondingly are above and below MD/BMD contact 234(3). Parts of an instance of VD/BVD contact 222 correspondingly are above and below MD/BMD contact 234(4). In FIG. 2A, SRAM 200 further includes gate-to-MD/BMD (GD) contacts 238(1)-238(4). Each of GD/BGD contacts 238(1)-238(2) represents two structures, namely an instance of a gate-to-above-MD (GAD) contact (e.g., 348(1)-348(2) FIG. 3C) that is formed around a portion of the N-type AR in a given CFET stack and an instance of a gate-to-below-BMD (GBD) contact (e.g., 350(1)-350(2) FIG. 3C) that is formed around a corresponding portion of the P-type AR in the given CFET stack. In some embodiments, each instance of the GAD contact is formed against one or more surfaces of the corresponding S/D region but not around the S/D region. In some embodiments, each instance of the GBD contact is formed against one or more surfaces of the corresponding S/D region but not around the S/D region.

GD/BGD contact 238(1) represents an instance of the GAD contact formed around a portion of the N-type AR in CFET stack 208(3) and an instance of the BGBD contact formed around a corresponding portion of the P-type AR in CFET stack 208(3). GD/BGD contact 238(2) represents an instance of the GAD contact formed around a portion of the N-type AR in CFET stack 208(3) and an instance of GBD contact formed around a corresponding portion of the P-type AR in CFET stack 208(3).

In FIG. 2A, SRAM 200 further includes gate-to-GD/BGD (G2D) contacts 246(1) and 246(2), long axes of which are parallel to the X-axis. G2D contact 246(1) is over and couples gate 226(3) to GD/BGD contact 238(1). G2D contact 246(2) is over and couples gate 226(1) to GD/BGD contact 238(2). In some embodiments, G2D contact 246(1) is under and couples gate 226(3) to GD/BGD contact 238(1). In some embodiments, G2D contact 246(2) is under and couples gate 226(1) to GD/BGD contact 238(2).

Relative to the Y-axis and the Z-axis, e.g., as shown in the sectional views of FIGS. 3A-3C corresponding to section lines IIIA-IIIA′, IIIB-IIB′ and IIIC-IIIC′ of FIG. 2A, SRAM 200 has a Z-shape including an arm, a body and a foot. The upper-half of CFET stack 208(1), the N-type AR of CFET stack 208(1), represents the arm of the Z-shape of SRAM 200. CFET stacks 208(2) and 208(3) represent the body of the Z-shape of SRAM 200. The lower-half of CFET stack 208(4), i.e., the P-type AR of CFET stack 208(4), represents the foot of the Z-shape of SRAM 200

Locations of the FETs of SRAM 100 of FIG. 1 in SRAM 200 of FIG. 2A are as follows: each of N1 and P1 of latch 102 is in CFET stack 208(2); each of N2 and P2 of latch 102 is in CFET stack 208(3); N3 of sub-port PRT1A of port PRT1 is in CFET 208(2); N4 of sub-port PRT1B of port PRT1 is in CFET 208(3); P3 of sub-port PRT2A of part PRT2 is in CFET 208(2); P4 of sub-port PRT2B of port PRT2 is in CFET 208(3); each of P5 and P6 of port PRT3 is in CFET 208(4); and each of N5 and N6 of port PRT4 is in CFET 208(1).

FIG. 2B is a layout diagram of SRAMs 200(1) and 200(2) for a semiconductor device, in accordance with some embodiments.

In FIG. 2B, each of SRAMs 200(1) and 200(2) is an instance of SRAM 200 of FIG. 2A. Relative to the Y-axis, SRAM 200(1) is abutted with SRAM 200(2). SRAM 200(1) is simply stacked on SRAM 200(2), i.e., SRAM 200(1) is not rotated rotation about either the Y-axis or the X-axis with respect to SRAM 200 of FIG. 2A.

Relative to the Y-axis, a top region of SRAM 200(2) overlaps a bottom region of SRAM 200(1) resulting in a merged/shared CFE stack that represents an upper-half of CFET stack 208(1) of SRAM 200, i.e., upper-half 208(1)_200(2) of SRAM 200(1) and a lower-half of CFET stack 208(4) of SRAM 200, i.e., lower-half 208(4)_200(1). The upper-half of CFET stack 208(1)_200(2) represents the arm of the Z-shape of SRAM 200(2). The lower-half of CFET stack 208(4)_200(1) represents the foot of the Z-shape of SRAM 200(1). As such, arm 208(1)_200(2) of the Z-shape of SRAM 200(2) overlaps (or nests) with foot 208(4)_200(1) of the Z-shape of SRAM 200(1), which conserves space/volume relative to the Y-axis. In some embodiments, such overlapping (or nesting) is referred to as a zigzag arrangement.

FIGS. 3A-3C are corresponding cross-sectional views 300A-300C of an SRAM for a semiconductor device, in accordance with some embodiments.

Cross-section 300A of FIG. 3A corresponds to section line IIIA-IIIA′ of FIG. 2A. Cross-section 300B of FIG. 3B corresponds to section line IIIB-IIIB′ of FIG. 2A. Cross-section 300C of FIG. 3C corresponds to section line IIIC-IIIC′ of FIG. 2A.

In FIGS. 3A-3C, as well as for the side views of FIGS. 3D-4E and 6A-6B, an orthogonal Cartesian coordinate system is assumed in which a first direction is parallel to the X-axis, a second direction is parallel to the Y-axis and a third direction is parallel to the Z-axis.

In FIGS. 3A-3C, CFET stacks 308(1)-308(4) correspond to CFET stacks 208(1)-208(4) of FIG. 2A. Gates 326(1)-326(4) correspond to gates 226(1)-226(4). Gates 328(1)-328(6) correspond to gates 228(1)-228(6). Gates 330(1)-330(6) correspond to gates 230(1)-230(6). G2D contacts 346(1) and 346(2) correspond to G2D contacts 246(1) and 246(2).

Relative to the Z-axis, gates 328(1)-328(6) are free from being coupled to corresponding overlying gates 330(1)-330(6) by corresponding instances of insulator 344. Relative to the Z-axis: gates 326(1) and 326(2) are coupled together by an instance of G2G contact 342; and gates 326(3) and 326(4) are coupled together by an instance of G2G contact 342. Relative to the Y-axis; gate 330(1) is wider than corresponding underlying gate 328(1) such that gate 330(1) abuts and is coupled to gate 326(1); and gate 328(6) is wider than corresponding overlying gate 330(6) such that gate 328(6) abuts and is coupled to gate 326(4).

Relative to the Z-axis: gate-to-above-MD (GAD) contact 348(1) and gate-to-below-BMD (GBD) contact 350(1) are coupled together by an instance of an MD-to-MD (D2D) contact 352; and GAD contact 348(2) and GBD contact 350(2) are coupled together by an instance of D2D contact 352. Considered together, GAD contact 348(1) and GBD contact 350(1) correspond to GD contact 238(1). Considered together, GAD contact 348(2) and GBD contact 350(2) correspond to GD contact 238(2).

GAD 348(1) is around S/D regions in the N-type AR of CFET stack 308(2) that correspond to N1 and N3. GAD 348(2) is around S/D regions in the N-type AR of CFET stack 308(3) that correspond to N4 and N2. GBD 350(1) is around S/D regions in the P-type AR of CFET stack 308(2) that correspond to P1 and P3. GBD 350(2) is around S/D regions in the P-type AR of CFET stack 308(3) that correspond to P4 and P2.

Regarding the N-type AR region of CFET stack 308(1), instead of gates 330(1) or 330(2), insulating dielectric (ILD) material 354 is formed around the S/D regions corresponding to N5 and N6 of cell region C(i). Regarding the P-type AR region of CFET stack 308(1), instead of gates 328(1) or 328(3), ILD material 354 is formed around the S/D regions corresponding to N5 and N5 of cell region C(i−1). Regarding the N-type AR region of CFET stack 308(4), instead of gates 330(5) or 330(6), ILD material 354 is formed around the S/D regions corresponding to N6 and N5 of cell region C(i+1). Regarding the P-type AR region of CFET stack 308(4), instead of gates 328(5) or 328(6), ILD material 354 is formed around the S/D regions corresponding to P6 and P5 of cell region C(i).

In FIGS. 3A-3C, the Z-shape of corresponding SRAMs 300A-300C is indicated by a Z-shape 362.

In cross-section 300A of FIG. 3A, Z-shape 362 encloses N1, N4, N5, P1, P4 and P6 of the corresponding SRAM cell region, namely C(i), where i is positive integer and 1≤0. While each of N6 and P5 is shown in FIG. 3A, nevertheless, each of N6 and P5 is included in other corresponding cell regions, i.e., neither of N6 and P5 is included in cell region C(i). N6 is included in a cell region C(i+1). Relative to the X-axis, cell region C(i+1) abuts a right side of cell region C(i) such that N6 of cell region C(i+1) overlaps (or nests) with P6 of cell region C(i). P5 is included in a cell region C(i−1). In some embodiments, each of cell regions C(i−1) and C(i+1) are instances of a Z-shaped SRAM such as SRAM 200.

In cross-section 300B of FIG. 3B, Z-shape 362 of the SRAM encloses N2, N3, N6, P2, P3 and P5. While each of N5 and P6 is shown in FIG. 3B, nevertheless, each of N5 and P6 is included in other corresponding cell regions, i.e., neither of N5 and P6 is included in cell region C(i). N5 is included in cell region C(i+1). P6 is included in cell region C(i−1). Relative to the X-axis, cell region C(i−) abuts a left side of cell region C(i) such that P6 of cell region C(i−) underlaps (or nests) with N6 of cell region C(i).

FIGS. 3D and 3E are side views of corresponding SRAMs for a semiconductor device, in accordance with some embodiments.

The side view of FIG. 3D corresponds to the side-view line IIID-IIID′ of FIG. 2B. The side view of FIG. 3E is from the same perspective as the side view of FIG. 3D.

Each of SRAM(i) 200(1) and SRAM(i+1) 200(2) is an example of SRAM 200 of FIG. 2A. In FIG. 3D, relative to the X-axis, port PRT4 of SRAM(i) 200(2) overlaps (or nests) with port PRT3 of SRAM(i) 200(1). Additional ports can be added to each of SRAM(i) 200(1) and SRAM(i+1) 200(2) to expand the sizes correspondingly thereof relative to the X-axis, as shown in FIG. 3E.

In FIG. 3E, SRAM(i) 300(1) and SRAM(i+1) 300(2) are corresponding variations of SRAM(i) 200(1) and SRAM(i+1) 200(2) of FIG. 3D. Also, in FIG. 3E, ports PRT3(1) and PRT4(1) correspond to ports PRT3 and PRT4 of FIG. 3D. Each of SRAM(i) 300(1) and SRAM(i+1) 300(2) further includes a port PRT3(2) and PRT4(2).

In FIG. 3E, relative to the X-axis: port PRT4(1) of SRAM(i) 300(2) overlaps (or nests) with port PRT3(2) of SRAM(i) 300(1); and port PRT4(2) of SRAM(i) 300(2) overlaps (or nests) with port PRT3(1) of SRAM(i) 300(1).

FIG. 4 is a schematic circuit diagram of an SRAM 400, in accordance with some embodiments.

SRAM 400 of FIG. 4 is similar to SRAM 100 of FIG. 1. For brevity, the discussion will focus more on differences between FIG. 4 and FIG. 1 than on similarities.

While SRAM 400 is a four port (4P) SRAM like SRAM 100, the third port (port PRT5) and the fourth port (port PRT6) of SRAM 400 are different than the corresponding third port (port PRT3) and fourth port (port PRT4) of SRAM 100. As a result, SRAM 400 further includes NFETs N7-N8 and PFETs P7-P8 but does not N5-N6 and P5-P6, as compared to SRAM 100.

In SRAM 400 of FIG. 4, Port PRT5 includes NFETs N7 and N8. The S/D terminals of N7 are correspondingly coupled to VSS and a first S/D terminal of N8. The second S/D terminal of N8 is coupled to bit line RBLA_FS. A gate terminal of N7 is coupled to corresponding S/D terminals of P2 and N2 at the second I/O node of latch 102. A gate terminal of N8 is coupled to word line RWLA_FS.

In SRAM 400, port PRT6 includes PFETs P7 and P8. The S/D terminals of P7 are correspondingly coupled between VDD and a first S/D terminal of P8. The second S/D terminal of P8 is coupled to a bit line RBLB_BS. A gate terminal of P7 is coupled to corresponding S/D terminals of P2 and N2 at the second I/O node of latch 102. As such, the gate terminals of P7 and N7 are also coupled to each other. A gate terminal of P8 is coupled to a word line RWLB_BS.

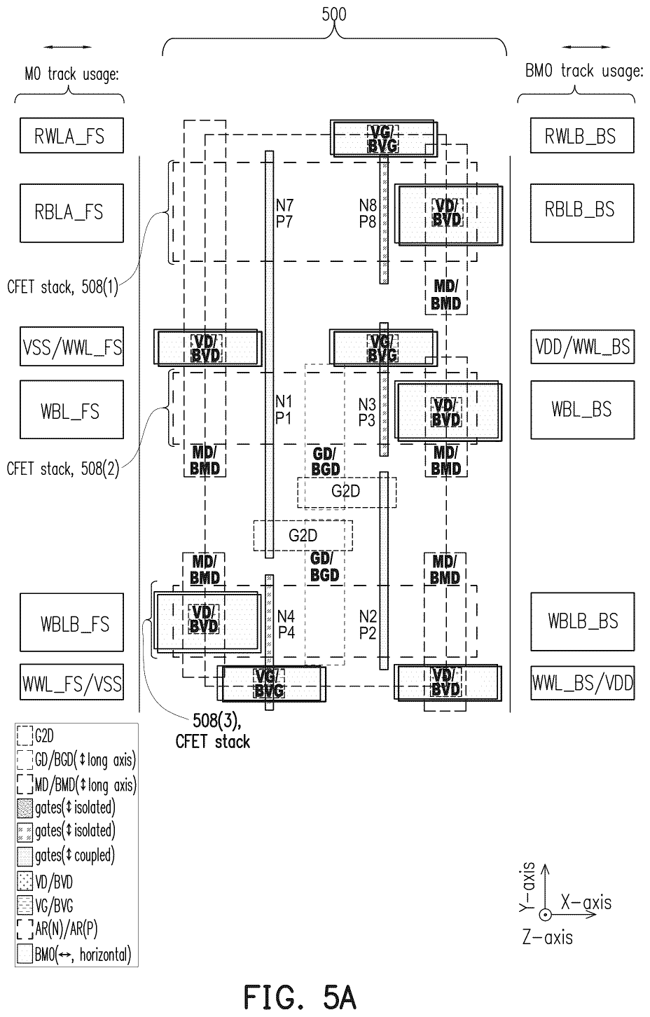

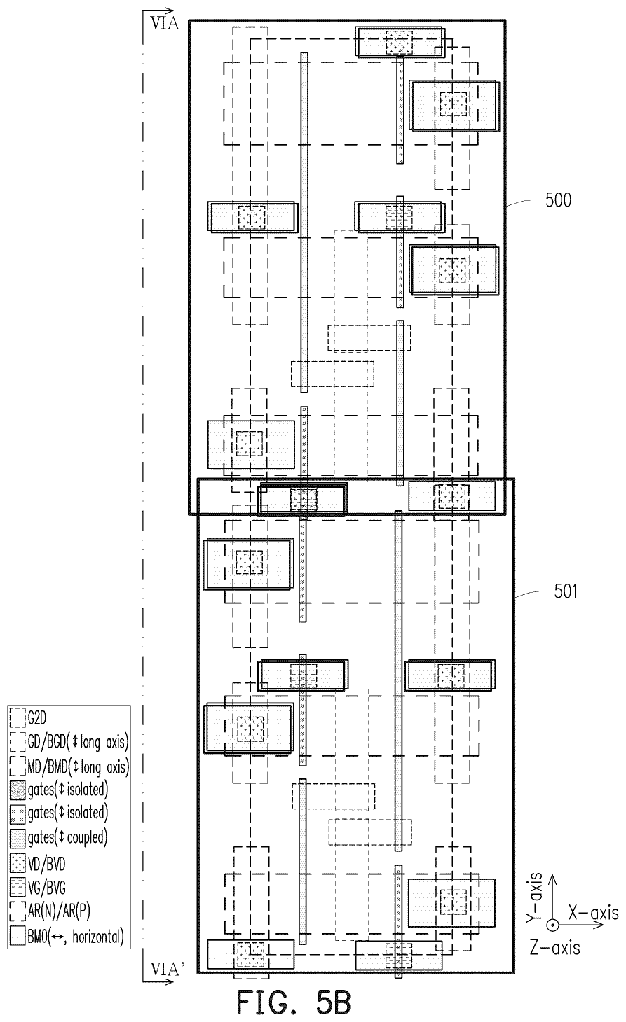

FIG. 5A is a layout diagram of an SRAM 500 for a semiconductor device, in accordance with some embodiments.

SRAM 500 of FIG. 5A is similar to SRAM 400 of FIG. 4. For brevity, the discussion will focus more on differences between FIG. 5A and FIG. 2A than on similarities.

Whereas SRAM 200 includes CFETs 208(1)-208(4), SRAM 500 includes CFET stacks 508(1)-508(3). CFET stacks 508(2)-508(3) correspond to CFETs 208(2)-208(3) of SRAM 200. CFET stack 508(1) corresponds to the upper-half of CFET 208(1) and to the lower-half of CFET 208(4). Relative to the Y-axis, SRAM 500 is more compact than SRAM 200.

Whereas SRAM 400 includes ports PRT5 and PRT6 but not ports PRT3 and PRT4, SRAM 500 includes corresponding FETs N7-N8 and P7-P8 but correspondingly does not include N5-N6 and P5-P6.

Relative to the Y-axis and the Z-axis, SRAM 500 has a rectangular parallelepiped (RP) shape. In some embodiments, the RP shape is alternatively referred to as a rectangular prism shape.

Locations of the FETs of SRAM 400 of FIG. 4 in SRAM 500 of FIG. 5A are as follows: each of N1 and P1 of latch 102 is in CFET stack 508(2); each of N2 and P2 of latch 102 is in CFET stack 508(3); N3 of sub-port PRT1A of port PRT1 is in CFET stack 508(2); N4 of sub-port PRT1B of port PRT1 is in CFET stack 508(3); P3 of sub-port PRT2A of part PRT2 is in CFET stack 508(2); P4 of sub-port PRT2B of port PRT2 is in CFET stack 508(3); each of N7 and N8 of port PRT5 is in CFET stack 508(1); and each of P7 and P8 of port PRT6 is in CFET stack 508(1).

FIG. 5B is a layout diagram of SRAMs 500 and 501 for a semiconductor device, in accordance with some embodiments.

In FIG. 5B. SRAM 501 is a version of SRAM 500 that has been flipped horizontally, i.e., rotated 180° about the Y-axis with respect to SRAM 500. SRAM 500 is simply stacked on SRAM 501. Relative to the Y-axis, where SRAM 500 and SRAM 501 overlap, they share the M0 and BM0 segments.

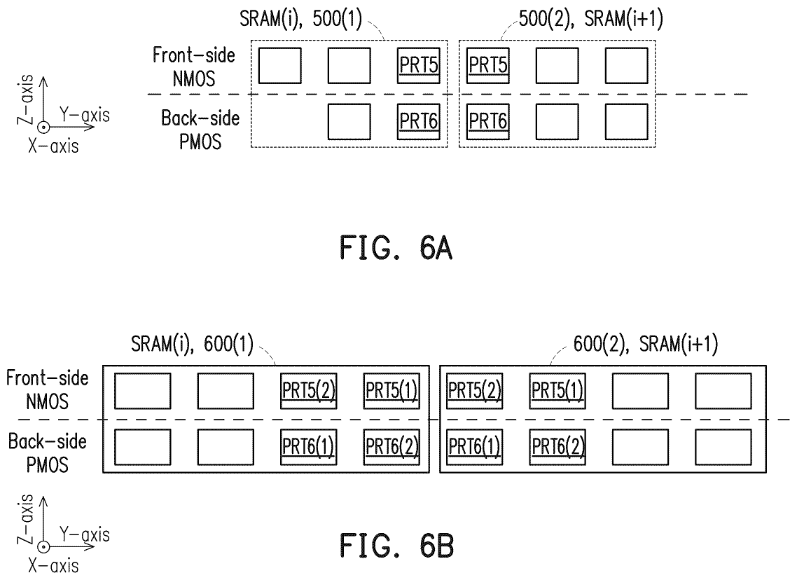

FIGS. 6A and 6B are side views of corresponding SRAMs for a semiconductor device, in accordance with some embodiments.

The side view of FIG. 6A corresponds to the side-view line VIA-VIA′ of FIG. 5B. The side view of FIG. 6B is from the same perspective as the side view of FIG. 6A.

Each of SRAM(i) 500(1) and SRAM(i+1) 500(2) is an example of SRAM 500 of FIG. 2A. In FIG. 6A, relative to the X-axis: port PRT5 of SRAM(i) 500(1) is adjacent to port PRT5 of SRAM(i) 500(2); and port PRT6 of SRAM(i) 500(1) is adjacent to port PRT6 of SRAM(i) 500(2). Additional ports can be added to each of SRAM(i) 500(1) and SRAM(i+1) 500(2) to expand the sizes correspondingly thereof relative to the X-axis, as shown in FIG. 6B.

In FIG. 6B, SRAM(i) 600(1) and SRAM(i+1) 600(2) are corresponding variations of SRAM(i) 500(1) and SRAM(i+1) 500(2) of FIG. 6A. Also, in FIG. 6B, ports PRT5(1) and PRT6(1) correspond to ports PRT5 and PRT6 of FIG. 6A. Each of SRAM(i) 600(1) and SRAM(i+1) 600(2) further includes a port PRT5(2) and PRT6(2).

In FIG. 6B, relative to the X-axis: port PRT5(1) of SRAM(i) 600(1) is adjacent to port PRT5(2) of SRAM(i) 600(2); port PRT6(2) of SRAM(i) 600(1) is adjacent to port PRT6(1) of SRAM(i) 600(2);
port PRT5(1) of SRAM(i) 600(i) is between port PRT5(2) of SRAM(i) 600(1) and port PRT5(2) of SRAM(i+1) 600(2); port PRT5(2) of SRAM(i+1) 600(2) is between port PRT5(1) of SRAM(i) 600(1) and port PRT5(1) of SRAM(i+1) 600(2); port PRT6(2) of SRAM(i) 600(i) is between port PRT6(1) of SRAM(i) 600(1) and port PRT6(1) of SRAM(i+1) 600(2); and port PRT6(1) of SRAM(i+1) 600(2) is between port PRT6(2) of SRAM(i) 600(1) and port PRT6(2) of SRAM(i+1) 600(2).

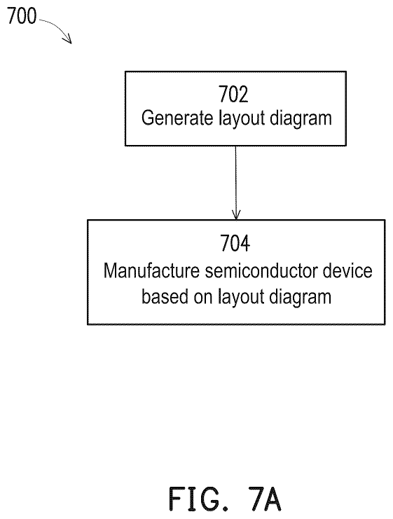

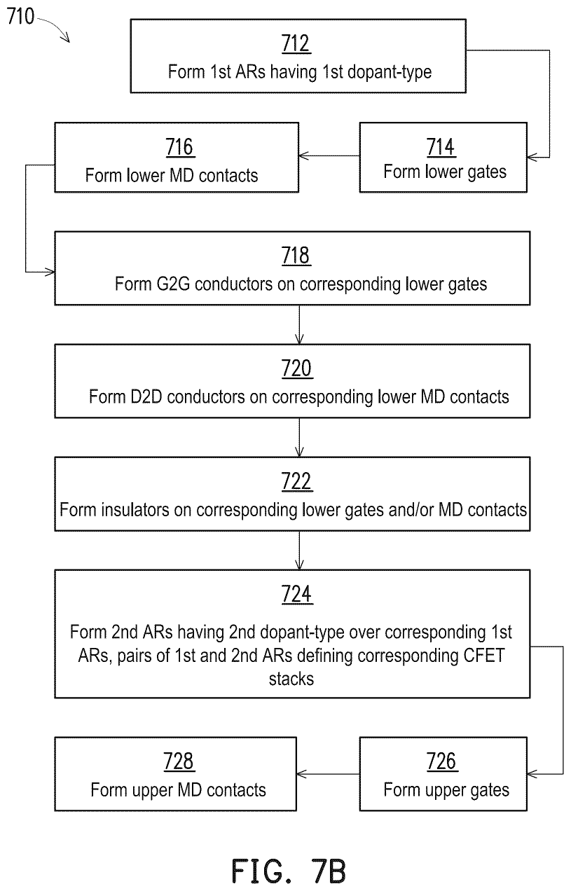

FIG. 7A is a flowchart 700 of a method of manufacturing a memory device, in accordance with some embodiments.

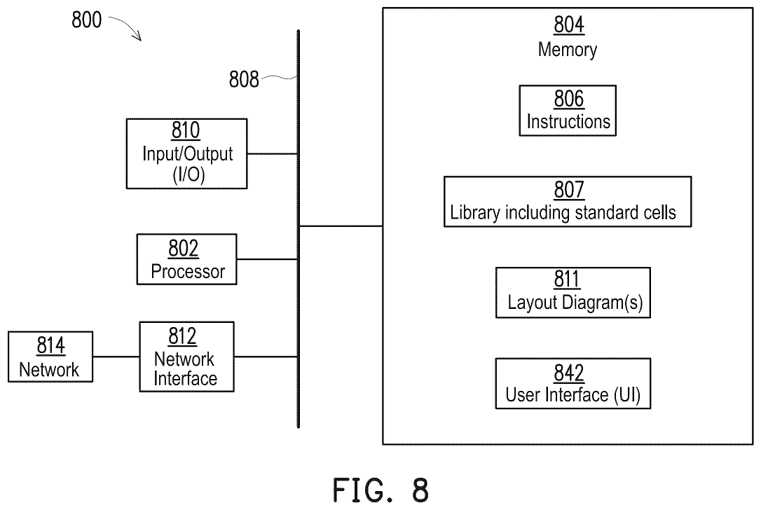

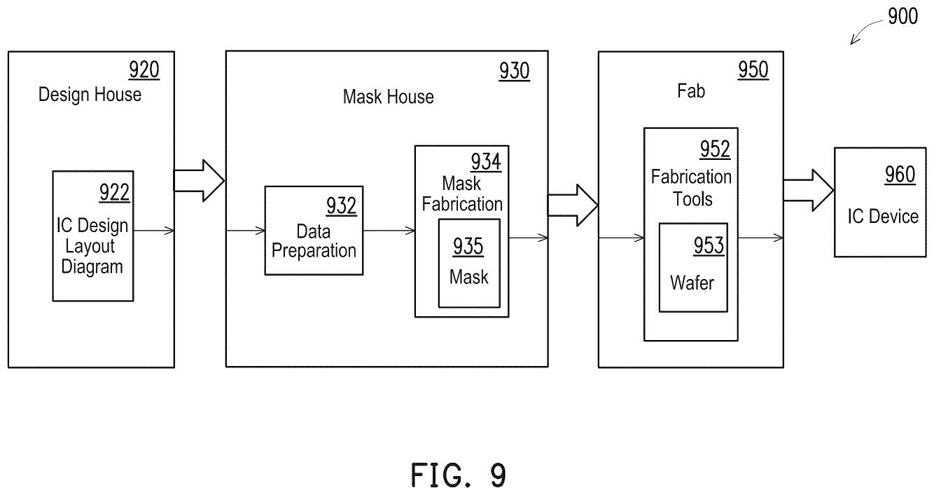

The method of flowchart (flow diagram) 700 is implementable, for example, using EDA system 800 (FIG. 8, discussed below) and an IC manufacturing system 900 (FIG. 9, discussed below), in accordance with some embodiments. Examples of a semiconductor device which can be manufactured according to the method of flowchart 700 include semiconductor devices based on the layout diagrams disclosed herein, or the like.

In FIG. 7, the method of flowchart 700 includes blocks 702-704. At block 702, a layout diagram is generated which, among other things, includes one or more of layout diagrams disclosed herein, or the like. Block 702 is implementable, for example, using EDA system 800 (FIG. 8, discussed below), in accordance with some embodiments. From block 702, flow proceeds to block 704.

At block 704, based on the layout diagram, at least one of (A) one or more photolithographic exposures are made or (b) one or more semiconductor masks are fabricated or (C) one or more components in a layer of a semiconductor device are fabricated. See discussion below of IC manufacturing system 900 in FIG. 9 below.

FIG. 7B is a flowchart 710 of a method of fabricating a semiconductor device, and more specifically an SRAM, in accordance with some embodiments.

Flowchart 710 is an example of block 704 of FIG. 7A. Flowchart 710 includes blocks 712-728. Examples provided in the context of the discussion of blocks 712-728 assume first, second and third orthogonal directions that are, e.g., correspondingly parallel to the X-axis, Y-axis and Z-axis. The method of flowchart 710 is implementable, for example, using IC manufacturing system 900 (FIG. 9, discussed below), in accordance with some embodiments. Examples of a semiconductor device which can be manufactured according to the method of flowchart 710 include semiconductor devices having SRAMS based on the layout diagrams disclosed herein, or the like.

Blocks 712-728 result, among other things in the formation of NFETs and PFETs.

In some embodiments, where active regions formed according to flowchart 710 are nanosheets such that the resultant transistors are nanosheet transistors, the flow of blocks 712-728 is an example of a more general flow for forming a device such as the following: the nanosheets, i.e., the active regions, are formed; then gates are formed; then MD contacts are formed; then G2G conductors are formed between corresponding gates; and then insulators are formed between corresponding MD contacts. In such embodiments, where the device has a CFET architecture such that the transistors are correspondingly arranged in CFET stacks, lower transistors are formed and then corresponding upper transistors are formed. In some embodiments, the sequence of flow is different.

At block 712, first active regions (ARs) are formed that have a first dopant-type, wherein portions of the first ARs are over the lower parts of the lower gates and over the lower parts of the lower MD contacts. Examples of the first ARs include the P-type ARs of CFET stacks 208(1)-208(4) of FIG. 2A, or the like. The formation of the ARs includes doping the first ARs with the first dopant-type. An example of the first dopant type is P-type dopant. From block 712, flow proceeds to block 714.

At block 714, lower gates are formed. Examples of the lower gates include gates 326(2), 328(1) and 328(4)-328(5) of FIG. 3A, gates 326(4), 328(3)-328(4) and 328(6) of FIG. 3B, or the like. From block 714, flow proceeds to block 716.

At block 716, lower metal-to-source/drain (MD) contacts are formed. Examples of the lower MD contacts include BMD contact 232(1) of FIG. 2A, the lower portions of MD/BMD contacts 234(1)-234(4) of FIG. 2A, or the like. From block 716, flow proceeds to block 718.

At block 718, gate-to-gate (G2G) contacts are formed on corresponding ones of the lower gates. Examples of the G2G contacts include instances of G2G contact 342 in FIGS. 3A-3B, or the like. From block 718, flow proceeds to block 720.

At block 720, MD-to-MD (D2D) contacts are formed on corresponding ones of the lower MD contacts. Examples of the D2D contacts include instances of D2D contact 352 in FIG. 3C, or the like. From block 720, flow proceeds to block 722.

At block 722, insulators are formed on corresponding ones of lower gates and/or MD contacts. Examples of the insulators include instances of insulator 344 of FIGS. 3A-3B, or the like. From block 722, flow proceeds to block 724.

At block 724, second ARs are formed that have a second dopant-type which is different than the first dopant, wherein portions of the second ARs are over the lower gates, the lower MD contacts and the insulators, and wherein the second ARs are correspondingly (A) over and (B) aligned with the first ARs. Examples of the second ARs include the N-type ARs of CFET stacks 208(1)-208(4) of FIG. 2A, or the like. The formation of the second ARs includes doping the second ARs with the second dopant-type. An example of the second dopant type is N-type dopant. From block 724, flow proceeds to block 726.

At block 726, upper gates are formed. Examples of the upper gates include gates 326(1), 330(1) and 330(4)-330(5) of FIG. 3A, gate 326(3), 330(2)-330(3) and 330(6) of FIG. 3B, or the like. From block 726, flow proceeds to block 728.

At block 728, upper MD contacts are formed. Examples of the upper MD contacts include MD contact 236(1) of FIG. 2A, the upper portions of MD/BMD contacts 234(1)-234(4) of FIG. 2A, or the like.

In some embodiments, pairs of corresponding ones of the second AR (e.g., N-type) stacked over corresponding ones of the first AR (e.g., P-type) define first, second, third and fourth CFET stacks for a Z-shape SRAM having a CFET architecture. An example of the Z-shape SRAM is SRAM 200 of FIG. 2A, or the like. Examples of the first to fourth CFET stacks of the Z-shaped SRAM correspondingly include CFET stacks 208(2), 208(3), 208(1) and 208(4), or the like.

In some embodiments, pairs of corresponding ones of the second AR (e.g., N-type) stacked over corresponding ones of the first AR (e.g., P-type) define first, second and third CFET stacks of an RP-shaped SRAM having a CFET architecture. An example of the RP-shaped SRAM is SRAM 500 of FIG. 5A, or the like. Examples of the first to third CFET stacks of the RP-shaped SRAM correspondingly include CFET stacks 508(2), 508(3) and 508(1) of FIG. 5A, or the like.

In the context of forming a Z-shaped SRAM (e.g., 200) according to some embodiments, blocks 712-728 result in the following: the first CFET stack (e.g., 208(2)) including N3 and P3 that comprise a first port (e.g., PRT1A) and a third port (e.g., PRT2A) of the SRAM; the second CFET stack (e.g., 208(3)) including N4 and P4 that comprise a second port (e.g., PRT1B) and a fourth port (e.g., PRT2B) of the SRAM; a lower half (e.g., P-type AR) of the fourth CFET stack (e.g., 208(4)) including P5 and P6 that comprise a fifth port (e.g., PRT3) of the SRAM; and an upper half (e.g., N-type AR) of the third CFET stack (e.g., 208(3)) including N5 and N6 that comprise a sixth port (e.g., PRT4) of the SRAM.

In the context of forming a Z-shaped SRAM (e.g., 200) according to some embodiments, blocks 712-728 result in the following: the first CFET stack (e.g., 508(2)) including N3 and P3 that comprise a first port (e.g., PRT1A) and a third port (e.g., PRT2A) of the SRAM; the second CFET stack (e.g., 508(3)) including N4 and P4 that comprise a second port (e.g., PRT1B) and a fourth port (e.g., PRT2B) of the SRAM; and the third CFET stack (e.g., 508(1)) including N7-N8 and P7-P8 that comprise correspondingly a fifth port (e.g., PRT5) and a sixth port (e.g., PRT6) of the SRAM.

In FIG. 7B, blocks 712-728 of flowchart 710 are shown as having the following sequence: block 712→block 714→block 716→block 718→block 720→block 722→block 724→block 726→block 728. In some embodiments, other sequences of blocks 712-728 are provided. In some embodiments, flowchart 710 is described as forming lower components before upper components. In some embodiments, flowchart 710 is rearranged to form upper components before lower components. In some embodiments, flowchart 710 is rearranged (and blocks 712-728 are correspondingly modified) to have following sequence: block 724→block 726→block 728→block 718→block 720→block 722→block 712→block 714→block 716.

In FIG. 7B, flowchart 710 shows the following sub-sequence: block 714→block 716. In some embodiments, block 716 precedes block 714 such FIG. 7B has the sub-sequence block 716→block 714.

In FIG. 7B, flowchart 710 shows the following sub-sequence: block 726→block 728. In some embodiments, block 728 precedes block 726 such FIG. 7B has the sub-sequence block 728→block 726.

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a hardware processor 802 and a non-transitory, computer-readable storage medium 804. Storage medium 804, amongst other things, is encoded with, i.e., stores, computer program code 806, i.e., a set of executable instructions. Execution of instructions 806 by hardware processor 802 represents (at least in part) an EDA tool which implements a portion or all of, e.g., the method of FIG. 5 (block 502), methods of generating layout diagrams such as FIGS. 2B-2R, methods of generating layout diagrams corresponding to block diagrams such as FIGS. 1A-1H, or the like, in accordance with one or more embodiments (hereinafter, the noted processes and/or methods). Storage medium 804, amongst other things, stores layout diagrams 811 such as the layout diagrams disclosed herein, other the like.

Processor 802 is electrically coupled to computer-readable storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and computer-readable storage medium 804 are capable of connecting to external elements via network 814. Processor 802 is configured to execute computer program code 806 encoded in computer-readable storage medium 804 in order to cause system 800 to be usable for performing a portion or all of the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, storage medium 804 stores computer program code 806 configured to cause system 800 (where such execution represents (at least in part) the EDA tool) to be usable for performing a portion or all of the noted processes and/or methods. In one or more embodiments, storage medium 804 further stores information which facilitates performing a portion or all of the noted processes and/or methods. In one or more embodiments, storage medium 804 stores library 807 of standard cells including such standard cells as disclosed herein. In some embodiments, storage medium 804 stores one or more layout diagrams 811.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 800.

System 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

Based on the layout diagram generated by block 502 of FIG. 5, the IC manufacturing system 900 implements block 504 of FIG. 5 wherein at least one of (A) one or more semiconductor masks or (B) at least one component in a layer of an inchoate semiconductor integrated circuit is fabricated using manufacturing system 900.

In FIG. 9. IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are be repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (c-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a static random access memory (SRAM) including: first and second CFET stacks, each of which includes a first active region (AR) having a first dopant-type stacked in a first direction on a second AR having a second dopant type different than the first dopant type, each CFET stack representing a complementary field-effect transistor (CFET) architecture; an upper half of a third CFET stack; a lower half of a fourth CFET stack; the first and second CFET stacks including field-effect transistors (FETs) that comprise a latch of the SRAM; the first CFET stack further including FETs that comprise first and third ports of the SRAM; the second CFET stack further including FETs that comprise second and fourth ports of the SRAM; the lower half of the fourth CFET stack including FETs that comprise a fifth port of the SRAM; and the upper half of the third CFET stack including FETs that comprise a sixth port of the SRAM.

In some embodiments, the latch of the of the SRAM includes first and second P-type FETs (PFETs) and first and second N-type FETs (NFETs); the first PFET and the first NFET are in the first CFET stack; and the second PFET and the second NFET are in the second CFET stack.

In some embodiments, the first port includes a third NFET that is in the first CFET stack; the first to fourth CFET stacks are spaced apart from each other relative to a second direction perpendicular to the first direction; and the third NFET is aligned with each of the second PFET and the second NFET relative to a third direction perpendicular to each of the first and second directions.

In some embodiments, the second port includes a third NFET that is in the second CFET stack; the first to fourth CFET stacks are spaced apart from each other relative to a second direction perpendicular to the first direction; and the third NFET is aligned with each of the first PFET and the first NFET relative to a third direction perpendicular to each of the first and second directions.

In some embodiments, the third port includes a third PFET that is in the first CFET stack; the first to fourth CFET stacks are spaced apart from each other relative to a second direction perpendicular to the first direction; and the third PFET is aligned with each of the second PFET and the second NFET relative to a third direction perpendicular to each of the first and second directions.

In some embodiments, the fourth port includes a third PFET that is in the second CFET stack; the first to fourth CFET stacks are spaced apart from each other relative to a second direction perpendicular to the first direction; and the third PFET is aligned with each of the first PFET and the first NFET relative to a third direction perpendicular to each of the first and second directions.

In some embodiments, the fifth port includes third and fourth PFETs that are in the lower half of the fourth CFET stack; the first to fourth CFET stacks are spaced apart from each other relative to a second direction perpendicular to the first direction; and the third PFET is aligned with each of the second PFET and the second NFET relative to a third direction perpendicular to each of the first and second directions; and the fourth PFET is aligned with each of the first PFET and the first NFET relative to the third direction.

In some embodiments, the sixth port includes third and fourth NFETs that are in the upper half of the first CFET stack; the first to fourth CFET stacks are spaced apart from each other relative to a second direction perpendicular to the first direction; and the third NFET is aligned with each of the second PFET and the second NFET relative to a third direction perpendicular to each of the first and second directions; and the fourth NFET is aligned with each of the first PFET and the first NFET relative to the third direction.

In some embodiments, the latch of the of the SRAM includes first and second P-type FETs (PFETs) and first and second N-type FETs (NFETs); the first port includes a third NFET that is in the first CFET stack; the third port includes a third PFET that is in the first CFET stack; the fifth port includes a fourth PFET that is in the lower half of the fourth CFET stack; the sixth port includes a fourth NFET that is in the upper half of the third CFET stack; the first to fourth CFET stacks are spaced apart from each other relative to a second direction perpendicular to the first direction; and the third and fourth NFETs and the third and fourth PFETs are aligned with each of the second PFET and the second NFET relative to a third direction perpendicular to each of the first and second directions.

In some embodiments, the SRAM further includes: a gate structure formed around corresponding portions of the first and second AR regions in the second CFET stack and the second AR region in the lower half of the fourth CFET stack; and wherein the gate structure represents a gate electrode that is coupled to each of the second NFET and the second and fourth PFETs.

In some embodiments, the latch of the of the SRAM includes first and second P-type FETs (PFETs) and first and second N-type FETs (NFETs); the second port includes a third NFET that is in the second CFET stack; the fourth port includes a third PFET that is in the second CFET stack; the fifth port includes a fourth PFET that is in the lower half of the fourth CFET stack; the sixth port includes a fourth NFET that is in the upper half of the third CFET stack; the first to fourth CFET stacks are spaced apart from each other relative to a second direction perpendicular to the first direction; and the third and fourth NFETs and the third and fourth PFETs are aligned with each of the first PFET and the first NFET relative to a third direction perpendicular to each of the first and second directions.

In some embodiments, the SRAM further includes: a gate structure formed around corresponding portions of the first AR region in the lower half of the third CFET stack and the first and second AR regions in the first CFET stack; and wherein the gate structure represents a gate electrode that is coupled to each of the first PFET and the first and fourth NFETs.

In some embodiments, the first and second CFET stacks are adjacent to each other relative to a second direction perpendicular to the first direction.

In some embodiments, relative to the second direction: the first CFET stack is between the second CFET stack and the upper half of the third CFET stack; and the second CFET stack is between the first CFET stack and the lower half of the fourth CFET stack.

In some embodiments, the first and second ARs of the first to fourth CFET stacks have corresponding widths W1, W2, W3 and W4 relative to a second direction perpendicular to the first direction; W1 of the first CFET stack is approximately equal to W2 of the second CFET stack such that W1≈W2; W3 of the third CFET stack is approximately equal to W4 of the fourth CFET stack such that W3≈W4; and (W1≈W2)<(W3≈W4).

In some embodiments, a SRAM includes a static random access memory (SRAM) including: first, second and third CFET stacks, each of which includes a first active region (AR) having a first dopant-type stacked in a first direction on a second AR having a second dopant type different than the first dopant type, each CFET stack representing a complementary field-effect transistor (CFET) architecture; the first and second CFET stacks including field-effect transistors (FETs) that comprise a latch of the SRAM; the first CFET stack further including FETs that comprise first and third ports of the SRAM; the second CFET stack further including FETs that comprise second and fourth ports of the SRAM; and the third CFET stack including FETs that comprise fifth and sixth ports of the SRAM.

In some embodiments, the latch of the of the SRAM includes first and second P-type FETs (PFETs) and first and second N-type FETs (NFETs); the first PFET and the first NFET are in the first CFET stack; the second PFET and the second NFET are in the second CFET stack; the first port includes a third NFET that is in the first CFET stack; the first to third CFET stacks are spaced apart from each other relative to a second direction perpendicular to the first direction; and the third NFET is aligned with each of the second PFET and the second NFET relative to a third direction perpendicular to each of the first and second directions.

In some embodiments, the latch of the of the SRAM includes first and second P-type FETs (PFETs) and first and second N-type FETs (NFETs); the first PFET and the first NFET are in the first CFET stack; the second PFET and the second NFET are in the second CFET stack; the second port includes a third NFET that is in the second CFET stack; the first to third CFET stacks are spaced apart from each other relative to a second direction perpendicular to the first direction; and the third NFET is aligned with each of the first PFET and the first NFET relative to a third direction perpendicular to each of the first and second directions.

In some embodiments, the latch of the of the SRAM includes first and second P-type FETs (PFETs) and first and second N-type FETs (NFETs); the first PFET and the first NFET are in the first CFET stack; the second PFET and the second NFET are in the second CFET stack; the third port includes a third PFET that is in the first CFET stack; the first to third CFET stacks are spaced apart from each other relative to a second direction perpendicular to the first direction; and the third PFET is aligned with each of the second PFET and the second NFET relative to a third direction perpendicular to each of the first and second directions.

In some embodiments, the latch of the of the SRAM includes first and second P-type FETs (PFETs) and first and second N-type FETs (NFETs); the first PFET and the first NFET are in the first CFET stack; the second PFET and the second NFET are in the second CFET stack; the fourth port includes a third PFET that is in the second CFET stack; the first to third CFET stacks are spaced apart from each other relative to a second direction perpendicular to the first direction; and the third PFET is aligned with each of the first PFET and the first NFET relative to a third direction perpendicular to each of the first and second directions.

In some embodiments, the first and second CFET stacks are adjacent to each other relative to a second direction perpendicular to the first direction.

In some embodiments, relative to the second direction, the first CFET stack is between the second CFET stack and the first CFET stack.

In some embodiments, the latch of the of the SRAM includes first and second P-type FETs (PFETs) and first and second N-type FETs (NFETs); the first PFET and the first NFET are in the first CFET stack; the second PFET and the second NFET are in the second CFET stack; the fifth port includes third and fourth NFETs that are in the third CFET stack; the first to third CFET stacks are spaced apart from each other relative to a second direction perpendicular to the first direction; the third NFET is aligned with each of the first PFET and the first NFET relative to a third direction perpendicular to each of the first and second directions; and the fourth NFET is aligned with each of the second PFET and the second NFET relative to the third direction.

In some embodiments, the latch of the of the SRAM includes first and second P-type FETs (PFETs) and first and second N-type FETs (NFETs); the first PFET and the first NFET are in the first CFET stack; the second PFET and the second NFET are in the second CFET stack; the sixth port includes third and fourth PFETs that are in the third CFET stack; the first to third CFET stacks are spaced apart from each other relative to a second direction perpendicular to the first direction; and the third PFET is aligned with each of the first PFET and the first NFET relative to a third direction perpendicular to each of the first and second directions; and the fourth PFET is aligned with each of the second PFET and the second NFET relative to the third direction.

In some embodiments, the latch of the of the SRAM includes first and second P-type FETs (PFETs) and first and second N-type FETs (NFETs); the first port includes a third NFET that is in the first CFET stack; the third port includes a third PFET that is in the first CFET stack; the fifth port includes a fourth NFET that is in the third CFET stack; the sixth port includes a fourth PFET that is in the third CFET stack; the first to third CFET stacks are spaced apart from each other relative to a second direction perpendicular to the first direction; and the third and fourth NFETs and the third and fourth PFETs are aligned with each of the second PFET and the second NFET relative to a third direction perpendicular to each of the first and second directions.

In some embodiments, the latch of the of the SRAM includes first and second P-type FETs (PFETs) and first and second N-type FETs (NFETs); the second port includes a third NFET that is in the second CFET stack; the fourth port includes a third PFET that is in the second CFET stack; the fifth port includes a fourth NFET that is in the third CFET stack; the sixth port includes a fourth PFET that is in the third CFET stack; the first to third CFET stacks are spaced apart from each other relative to a second direction perpendicular to the first direction; and the third and fourth NFETs and the third and fourth PFETs are aligned with each of the second PFET and the second NFET relative to a third direction perpendicular to each of the first and second directions.

In some embodiments, the SRAM further including: a gate structure formed around corresponding portions of the first and second AR regions of the third CFET stack and the first and second AR regions in the first CFET stack and wherein the gate structure represents a gate electrode that is coupled to each of the first and fourth PFETs and the first and fourth NFETs.

In some embodiments, the first and second ARs of the first to third CFET stacks have corresponding widths W1, W2 and W3 relative to a second direction perpendicular to the first direction; W1 of the first CFET stack is approximately equal to W2 of the second CFET stack such that W1≈W2; and W3 of the third CFET stack is approximately equal to W4 of the fourth CFET stack such that W3≈W4; and (W1≈W2)<W3.

In some embodiments, a method (of manufacturing a static random access memory (SRAM)) includes: forming first active regions (ARs) having a first dopant-type; forming lower gates correspondingly at least partially around corresponding ones of the first ARs; forming lower metal-to-source/drain (MD) contacts correspondingly at least partially around corresponding ones of the first ARs; forming gate-to-gate (G2G) contacts on corresponding ones of the lower gates; forming drain-to-drain (D2D) contacts on corresponding ones of the lower MD contacts; forming insulators corresponding ones of the lower gates or the lower MD contacts; forming second ARs having a second dopant-type different than the first dopant type, the second ARs being over the G2G contacts, the D2D contacts and the insulators, and the second ARs being correspondingly (A) over and (B) aligned with the first ARs; pairs of corresponding ones of the second AR stacked over corresponding ones of the first AR defining first, second, third and fourth CFET stacks each of which represents a complementary field-effect transistor (CFET) architecture; forming upper gates at least partially around portions of corresponding ones of the second ARs, and correspondingly on the G2G contacts or the insulators; forming upper MD contacts correspondingly at least partially around portions of corresponding ones of the second ARs, and correspondingly on the D2D contacts or the insulators; the first and second CFET stacks including field-effect transistors (FETs) that comprise a latch of the SRAM; the first CFET stack further including FETs that comprise first and third ports of the SRAM; the second CFET stack further including FETs that comprise second and fourth ports of the SRAM; a lower half of the fourth CFET stack including FETs that comprise a fifth port of the SRAM; and the upper half of the third CFET stack including FETs that comprise a sixth port of the SRAM.

In some embodiments, the method further includes: forming buried via-to-lower-gate (BVG) contacts under corresponding portions of the lower gates; forming buried via-to-S/D-contact (BVD) contacts under corresponding portions of the lower MD contacts; and in an underlying layer of metallization, forming underlying conductors having portions correspondingly under the BVG contacts or the BVD contacts.

In some embodiments, the method further includes forming via-to-gate (VG) contacts on corresponding portions of the upper gates; and forming via-to-S/D-contact (VD) contacts on corresponding portions of the upper MD contacts; and in an overlying layer of metallization, forming overlying conductors having portions correspondingly over the VG contacts or the VD contacts.

In some embodiments, the forming first active regions (ARs) includes: forming first source/drain (S/D) regions including doping first areas of the first ARs, the first S/D regions representing first transistor-components of the FETs, wherein second areas of the first ARs which are between corresponding first S/D regions are first channel regions representing second transistor-components of the FETs; corresponding ones of the lower gate structures represent third transistor-components of the FETs; corresponding ones of the lower MD contacts structures represent fourth transistor-components of the FETs; the forming second ARs includes: forming second S/D regions including doping first areas of the second ARs, the second S/D regions representing fifth transistor-components of the FETs, wherein second areas of the second ARs which are between corresponding second S/D regions are second channel regions representing sixth transistor-components of the FETs; corresponding ones of the upper gate structures represent seventh transistor-components of the FETs; and corresponding ones of the lower MD contacts structures represent eighth transistor-components of the FETs.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A static random access memory (SRAM) comprising:
first and second CFET stacks, each of which includes a first active region (AR) having a first dopant-type stacked in a first direction on a second AR having a second dopant type different than the first dopant type, each CFET stack representing a complementary field-effect transistor (CFET) architecture;
an upper half of a third CFET stack;
a lower half of a fourth CFET stack;
the first and second CFET stacks including field-effect transistors (FETs) that comprise a latch of the SRAM;
the first CFET stack further including FETs that comprise first and third ports of the SRAM;
the second CFET stack further including FETs that comprise second and fourth ports of the SRAM;
the lower half of the fourth CFET stack including FETs that comprise a fifth port of the SRAM; and
the upper half of the third CFET stack including FETs that comprise a sixth port of the SRAM.

2. The SRAM of claim 1, wherein:
the latch of the of the SRAM includes first and second P-type FETs (PFETs) and first and second N-type FETs (NFETs);
the first PFET and the first NFET are in the first CFET stack; and
the second PFET and the second NFET are in the second CFET stack.

3. The SRAM of claim 2, wherein:
the first port includes a third NFET that is in the first CFET stack;
the first to fourth CFET stacks are spaced apart from each other relative to a second direction perpendicular to the first direction; and
the third NFET is aligned with each of the second PFET and the second NFET relative to a third direction perpendicular to each of the first and second directions.

4. The SRAM of claim 2, wherein:
the second port includes a third NFET that is in the second CFET stack;
the first to fourth CFET stacks are spaced apart from each other relative to a second direction perpendicular to the first direction; and
the third NFET is aligned with each of the first PFET and the first NFET relative to a third direction perpendicular to each of the first and second directions.

5. The SRAM of claim 2, wherein:
the third port includes a third PFET that is in the first CFET stack;
the first to fourth CFET stacks are spaced apart from each other relative to a second direction perpendicular to the first direction; and
the third PFET is aligned with each of the second PFET and the second NFET relative to a third direction perpendicular to each of the first and second directions.

6. The SRAM of claim 2, wherein:
the fourth port includes a third PFET that is in the second CFET stack;
the first to fourth CFET stacks are spaced apart from each other relative to a second direction perpendicular to the first direction; and
the third PFET is aligned with each of the first PFET and the first NFET relative to a third direction perpendicular to each of the first and second directions.

7. The SRAM of claim 2, wherein:
the fifth port includes third and fourth PFETs that are in the lower half of the fourth CFET stack;
the first to fourth CFET stacks are spaced apart from each other relative to a second direction perpendicular to the first direction; and
the third PFET is aligned with each of the second PFET and the second NFET relative to a third direction perpendicular to each of the first and second directions; and
the fourth PFET is aligned with each of the first PFET and the first NFET relative to the third direction.

8. The SRAM of claim 2, wherein:
the sixth port includes third and fourth NFETs that are in the upper half of the first CFET stack;
the first to fourth CFET stacks are spaced apart from each other relative to a second direction perpendicular to the first direction; and
the third NFET is aligned with each of the second PFET and the second NFET relative to a third direction perpendicular to each of the first and second directions; and
the fourth NFET is aligned with each of the first PFET and the first NFET relative to the third direction.

9. The SRAM of claim 1, wherein:
the latch of the of the SRAM includes first and second P-type FETs (PFETs) and first and second N-type FETs (NFETs);
the first port includes a third NFET that is in the first CFET stack;
the third port includes a third PFET that is in the first CFET stack;
the fifth port includes a fourth PFET that is in the lower half of the fourth CFET stack;
the sixth port includes a fourth NFET that is in the upper half of the third CFET stack;
the first to fourth CFET stacks are spaced apart from each other relative to a second direction perpendicular to the first direction; and
the third and fourth NFETs and the third and fourth PFETs are aligned with each of the second PFET and the second NFET relative to a third direction perpendicular to each of the first and second directions.

10. The SRAM of claim 9, further comprising:
a gate structure formed around corresponding portions of the first and second AR regions in the second CFET stack and the second AR region in the lower half of the fourth CFET stack; and
wherein the gate structure represents a gate electrode that is coupled to each of the second NFET and the second and fourth PFETs.

11. The SRAM of claim 1, wherein:
the latch of the of the SRAM includes first and second P-type FETs (PFETs) and first and second N-type FETs (NFETs);
the second port includes a third NFET that is in the second CFET stack;
the fourth port includes a third PFET that is in the second CFET stack;
the fifth port includes a fourth PFET that is in the lower half of the fourth CFET stack;
the sixth port includes a fourth NFET that is in the upper half of the third CFET stack;
the first to fourth CFET stacks are spaced apart from each other relative to a second direction perpendicular to the first direction; and
the third and fourth NFETs and the third and fourth PFETs are aligned with each of the first PFET and the first NFET relative to a third direction perpendicular to each of the first and second directions.

12. The SRAM of claim 11, further comprising:
a gate structure formed around corresponding portions of the first AR region in the lower half of the third CFET stack and the first and second AR regions in the first CFET stack and
wherein the gate structure represents a gate electrode that is coupled to each of the first PFET and the first and fourth NFETs.

13. A static random access memory (SRAM) comprising:
first, second and third CFET stacks, each of which includes a first active region (AR) having a first dopant-type stacked in a first direction on a second AR having a second dopant type different than the first dopant type, each CFET stack representing a complementary field-effect transistor (CFET) architecture;
the first and second CFET stacks including field-effect transistors (FETs) that comprise a latch of the SRAM;
the first CFET stack further including FETs that comprise first and third ports of the SRAM;
the second CFET stack further including FETs that comprise second and fourth ports of the SRAM; and
the third CFET stack including FETs that comprise fifth and sixth ports of the SRAM.

14. The SRAM of claim 13, wherein:
the latch of the of the SRAM includes first and second P-type FETs (PFETs) and first and second N-type FETs (NFETs);
the first PFET and the first NFET are in the first CFET stack;
the second PFET and the second NFET are in the second CFET stack;
the first port includes a third NFET that is in the first CFET stack;
the first to third CFET stacks are spaced apart from each other relative to a second direction perpendicular to the first direction; and
the third NFET is aligned with each of the second PFET and the second NFET relative to a third direction perpendicular to each of the first and second directions.

15. The SRAM of claim 13, wherein:
the latch of the of the SRAM includes first and second P-type FETs (PFETs) and first and second N-type FETs (NFETs);
the first PFET and the first NFET are in the first CFET stack;
the second PFET and the second NFET are in the second CFET stack;
the second port includes a third NFET that is in the second CFET stack;
the first to third CFET stacks are spaced apart from each other relative to a second direction perpendicular to the first direction; and
the third NFET is aligned with each of the first PFET and the first NFET relative to a third direction perpendicular to each of the first and second directions.

16. The SRAM of claim 13, wherein:
the latch of the of the SRAM includes first and second P-type FETs (PFETs) and first and second N-type FETs (NFETs);
the first PFET and the first NFET are in the first CFET stack; and
the second PFET and the second NFET are in the second CFET stack.
the third port includes a third PFET that is in the first CFET stack;
the first to third CFET stacks are spaced apart from each other relative to a second direction perpendicular to the first direction; and
the third PFET is aligned with each of the second PFET and the second NFET relative to a third direction perpendicular to each of the first and second directions.

17. The SRAM of claim 13, wherein:
the latch of the of the SRAM includes first and second P-type FETs (PFETs) and first and second N-type FETs (NFETs);
the first PFET and the first NFET are in the first CFET stack;
the second PFET and the second NFET are in the second CFET stack;
the fourth port includes a third PFET that is in the second CFET stack;
the first to third CFET stacks are spaced apart from each other relative to a second direction perpendicular to the first direction; and
the third PFET is aligned with each of the first PFET and the first NFET relative to a third direction perpendicular to each of the first and second directions.

18. A method of manufacturing a static random access memory (SRAM), the method comprising:
forming first active regions (ARs) having a first dopant-type;
forming lower gates correspondingly at least partially around portions of corresponding ones of the first ARs;
forming lower metal-to-source/drain (MD) contacts at least partially around corresponding ones of the first ARs;
forming gate-to-gate (G2G) contacts on corresponding ones of the lower gates;
forming drain-to-drain (D2D) contacts on corresponding ones of the lower MD contacts; and
forming insulators on corresponding ones of the lower gates or the lower MD contacts;
forming second ARs having a second dopant-type different than the first dopant type, the second ARs being over the G2G contacts, the D2D contacts and the insulators, and the second ARs being correspondingly (A) over and (B) aligned with the first ARs;
pairs of a corresponding one of the second ARs stacked over a corresponding one of the first ARs defining first, second, third and fourth CFET stacks each of which represents a complementary field-effect transistor (CFET) architecture;
forming upper gates at least partially around portions of corresponding ones of the second ARs, and correspondingly on the G2G contacts or the insulators; and
forming upper MD contacts correspondingly at least partially around portions of corresponding ones of the second ARs, and correspondingly on the D2D contacts or the insulators;
the first and second CFET stacks including field-effect transistors (FETs) that comprise a latch of the SRAM;
the first CFET stack further including FETs that comprise first and third ports of the SRAM;
the second CFET stack further including FETs that comprise second and fourth ports of the SRAM;
a lower half of the fourth CFET stack including FETs that comprise a fifth port of the SRAM; and
the upper half of the third CFET stack including FETs that comprise a sixth port of the SRAM.

19. The method of claim 18, further comprising:
forming buried via-to-lower-gate (BVG) contacts under corresponding portions of the lower gates;
forming buried via-to-S/D-contact (BVD) contacts under corresponding portions of the lower MD contacts; and
in an underlying layer of metallization, forming underlying conductors having portions correspondingly under the BVG contacts or the BVD contacts.

20. The method of claim 18, further comprising:
forming via-to-gate (VG) contacts on corresponding portions of the upper gates;
forming via-to-S/D-contact (VD) contacts on corresponding portions of the upper MD contacts; and
in an overlying layer of metallization, forming overlying conductors having portions correspondingly over the VG contacts or the VD contacts.
